(19) United States
(12) Patent Application Publication
(10) Pub. No.: US 2026/0150462 A1
(43) Pub. Date: May 28, 2026

(54) DISPLAY DEVICE

(71) Applicant: LG Display Co., Ltd., Seoul (KR)

(72) Inventors: HoJin Ryu, Goyang-si (KR); HeumeIl Baek, Seoul (KR)

(73) Assignee: LG Display Co., Ltd., Seoul (KR)

(21) Appl. No.: 19/307,400

(22) Filed: Aug. 22, 2025

(30) Foreign Application Priority Data
Nov. 28, 2024 (KR) 10-2024-0174036

(51) Int. Cl. H10H 29/49; H10H 29/41

(52) U.S. Cl. CPC H10H 29/49; H10H 29/41

(57) ABSTRACT

A display device according to an aspect of the present disclosure includes a substrate, a plurality of reflection electrodes on the substrate, a plurality of boding layers on at least one of the plurality of reflection electrodes, a plurality of light emitting diodes respectively on the plurality of bonding layers, a plurality of conductive layers spaced apart from each other and protruding out respectively from side surfaces of the plurality of light emitting diodes, and at least one connection electrode on the plurality of light emitting diodes. Accordingly, a short-circuit potentially caused by a patterning defect in the plurality of bonding layers may be suppressed.

### CROSS-REFERENCE TO RELATED APPLICATION

This application claims the priority of Korean Patent Application No. 10-2024-0174036, filed on Nov. 28, 2024, in the Korean Intellectual Property Office, the disclosure of which is incorporated herein by reference.

### BACKGROUND

### Field

The present disclosure relates to a display device and, more particularly, to a display device which includes a light emitting diode disposed on a bonding layer including a conductive material.

### Description of the Related Art

Display devices used for a monitor of a computer, a television, or a cellular phone include, among others, an organic light emitting display device (OLED), which is a self-emitting device, and a liquid crystal display device (LCD), which requires a separate light source.

As applications for display devices are becoming more diversified, for example, from personal digital assistants to monitors of computers and televisions, a display device with a large display area and reduced volume and weight is being studied.

Further, recently, a display device including a light emitting diode (LED) is attracting attention as a next generation display device. Since the LED is formed of an inorganic material, rather than an organic material, its reliability is excellent so that its lifespan is longer than that of the liquid crystal display device or the organic light emitting display device. Further, the LED has a relatively fast lighting speed, excellent luminous efficiency, and a strong impact resistance so that its stability is excellent, and an image having a high luminance may be displayed.

### SUMMARY

An object of the present disclosure is to provide a display device which suppresses a short-circuit due to a patterning defect of a bonding layer and a connection electrode.

Another object of the present disclosure is to provide a display device which suppresses a short-circuit caused by a patterning defect of a plurality of electrodes corresponding to the plurality of light emitting diodes.

Still another object of the present disclosure is to provide a display device with an improved luminous efficiency.

Objects of the present disclosure are not limited to the above-mentioned objects, and other objects, which are not mentioned above, can be clearly understood by those skilled in the art from the following descriptions.

To achieve these objects and other advantages and in accordance with the purpose of the present disclosure, as embodied and broadly described herein, a display device according to an aspect of the present disclosure includes a substrate, a plurality of reflection electrodes on the substrate, a plurality of boding layers on at least one of the plurality of reflection electrodes, a plurality of light emitting diodes respectively on the plurality of bonding layers, a plurality of conductive layers spaced apart from each other and protruding out respectively from side surfaces of the plurality of light emitting diodes, and at least one connection electrode on the plurality of light emitting diodes. Accordingly, a short-circuit potentially caused by a patterning defect in the plurality of bonding layers may be suppressed.

In another aspect of the present disclosure, a display device includes: a substrate; a power line on the substrate; a plurality of transistors on the substrate; a first reflection electrode connected to the power line; a plurality of second reflection electrodes connected to the plurality of transistors, respectively; a plurality of bonding layers on the first reflection electrode or respectively on the plurality of second reflection electrodes; a plurality of light emitting diodes respectively on the plurality of bonding layers; a plurality of conductive layers respectively covering a part of side surfaces of the plurality of light emitting diodes, an end of one of the plurality of conductive layers protruding farther out from a side surface of a corresponding one of the plurality of light emitting diodes than an end of a corresponding one of the plurality of bonding layers does; and at least one connection electrode connected to the first reflection electrode or respectively to the plurality of second reflection electrodes. Accordingly, a short-circuit potentially caused by a patterning defect in the plurality of bonding layers or at least one connection electrode may be suppressed.

Other detailed matters of various example embodiments are included in the detailed description and the drawings.

According to example embodiments of the present disclosure, in the display device, where a plurality of bonding layers are formed so as to correspond to the plurality of light emitting diodes, respectively, a potential short-circuit defect due to the plurality of bonding layers being not completely separated may be suppressed.

According to example embodiments of the present disclosure, in the display device, during a process of patterning a plurality of connection electrodes so as to correspond to the plurality of light emitting diodes, respectively, a potential short-circuit defect due to the plurality of connection electrodes being not completely separated may be suppressed.

According to example embodiments of the present disclosure, in the display device, light emitted from the plurality of light emitting diodes is upwardly reflected by a plurality of conductive layers protruding from a side surface of the light emitting diode to improve the luminous efficiency.

According to example embodiments of the present disclosure, in the display device, light emitted from the light emitting diode is upwardly reflected to improve the light extraction efficiency. Therefore, the display device of according to example embodiments of the present disclosure may be driven with a lower power.

The effects according to the present disclosure are not limited to the contents exemplified above, and various additional effects may be attained from the present disclosure.

The objects to be achieved by the present disclosure, the means for achieving the objects, and the effects of the present disclosure described above do not specify essential features of the claims. Thus, the scope of the claims is not limited to the above description or the below detailed description of the example embodiments of the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic diagram of a display device according to an example embodiment of the present disclosure;

FIG. 2 is a plan view of a pixel of a display device according to an example embodiment of the present disclosure;

FIG. 3 is a cross-sectional view along line A-A′ in FIG. 2;

FIGS. 4A to 4F are process diagrams for explaining a manufacturing method of a pixel of a display device according to an example embodiment of the present disclosure;

FIG. 5 is a plan view of a pixel of a display device according to another example embodiment of the present disclosure;

FIG. 6 is a cross-sectional view along line B-B′ in FIG. 5;

FIGS. 7A to 7G are process diagrams for explaining a manufacturing method of a pixel of a display device according to another example embodiment of the present disclosure;

FIG. 8 is a cross-sectional view of a pixel of a display device according to still another example embodiment of the present disclosure; and

FIG. 9 is a cross-sectional view of a pixel of a display device according to still another example embodiment of the present disclosure.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein and may be implemented in various other forms. The example embodiments are provided by way of example only so that those skilled in the art can more fully understand the features and aspects of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure.

Such terms as “including,” “having,” and “consist of,” where used herein, are generally intended to allow other components to be added unless the terms are used with a more limiting term like “only.” Any references to singular may include plural, and vice versa, unless expressly stated otherwise.

Components are to be interpreted to include an ordinary error range even if not expressly stated.

Where the position relation between two parts is described using such terms as “on,” “above,” “below,” and “next,” one or more parts may be positioned between the two parts unless the terms are used with a more limiting term like “immediately” or “directly.”

Where an element or layer is described as being disposed “on” another element or layer, the element or layer may be disposed directly on the other element or layer, or an additional layer or element may be interposed therebetween.

Although the terms “first,” “second,” and the like may be used for describing various components, these components are not confined by these terms. These terms are merely used to refer to one component separately from the other components. Therefore, a first component to be mentioned below may be a second component, and vice versa, in a technical concept of the present disclosure.

Like reference numerals generally denote like elements throughout the specification unless otherwise specified.

A size and a thickness of each component illustrated in the drawing are illustrated for convenience of description, and the present disclosure is not limited to the size and the thickness of the component illustrated.

The features of various example embodiments of the present disclosure can be partially or entirely adhered to or combined with each other and can be interlocked and operated in technically various ways, and the example embodiments can be carried out independently of or in association with each other.

Hereinafter, a display device according to example embodiments of the present disclosure will be described in detail with reference to accompanying drawings.

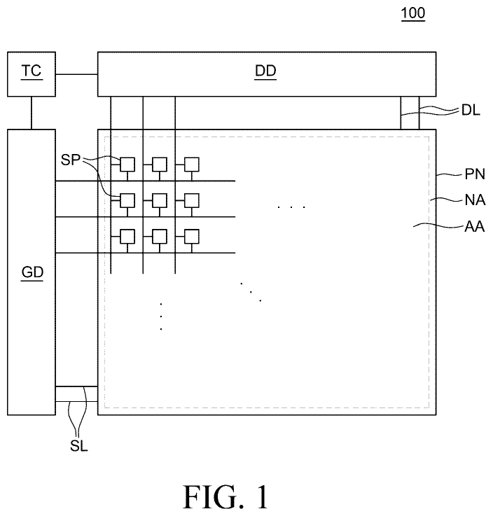

FIG. 1 is a schematic diagram of a display device according to an example embodiment of the present disclosure.

In FIG. 1, for the convenience of description, among various components of the display device 100, only a display panel PN, a gate driver GD, a data driver DD, and a timing controller TC are illustrated.

As shown in FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals respectively to a plurality of scan lines SL according to a plurality of gate control signals supplied from the timing controller TC. Even though FIG. 1 illustrates that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from an external source (e.g., a host system) to supply the image data to the data driver DD. The timing controller TC may generate a gate control signal and a data control signal using synchronization signals input from the external source, such as a dot clock signal, a data enable signal, and horizontal/vertical synchronization signals. Further, the timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other, and the plurality of sub pixels SP are connected to the scan lines SL and the data lines DL, respectively. In addition, even though not illustrated in the drawing, each of the plurality of sub pixels SP may be connected to a high potential power line, a low potential power line, and a reference line.

In the display panel PN, an active area AA and a non-active area NA enclosing the active area AA may be defined.

The active area AA is an area in which images are displayed in the display device 100. In the active area AA, a plurality of sub pixels SP which configure a plurality of pixels PX and a circuit for driving the plurality of sub pixels SP may be disposed. A sub pixel SP is a minimum unit which configures the active area AA, and n sub pixels SP form one pixel PX. In each of the plurality of sub pixels SP, a light emitting diode and a thin film transistor for driving the light emitting diode may be disposed. The plurality of light emitting diodes may be defined in different manners depending on the type of the display panel PN. For example, where the display panel PN is an inorganic light emitting display panel PN, the light emitting diode may be a light emitting diode (LED) or a micro light emitting diode (micro LED).

In the active area AA, a plurality of signal lines configured to transmit various signals to the plurality of sub pixels SP are disposed. For example, the plurality of signal lines include a plurality of data lines DL configured to supply a data voltage to the plurality of sub pixels SP and a plurality of scan lines SL configured to supply a gate voltage to the plurality of sub pixels SP. The plurality of scan lines SL extend in one direction in the active area AA to be connected to the plurality of sub pixels SP, and the plurality of data lines DL extend in a direction different from the one direction in the active area AA to be connected to the plurality of sub pixels SP. In addition, in the active area AA, a low potential power line and a high potential power line may be further disposed, but present disclosure is not limited thereto.

The non-active area NA is an area where images are not displayed so that the non-active area NA may be defined as an area outside and extending from the active area AA. In the non-active area NA, a link line configured to transmit a signal to the sub pixel SP of the active area AA, a pad electrode, or a driving IC, such as a gate driver IC or a data driver IC, may be disposed.

In another aspect, the non-active area NA may be located on a rear surface of the display panel PN, that is, a surface on which the sub pixels SP are not disposed or are omitted, and is not limited as illustrated in the drawing.

In another aspect, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC may be formed in separate flexible film(s) and printed circuit board(s) and may be electrically connected to the display panel PN by bonding the flexible film(s) and the printed circuit board(s) to a pad electrode formed in the non-active area NA of the display panel PN. If the gate driver GD is mounted in the GIP manner and the data driver DD and the timing controller TC transmit a signal to the display panel PN through a pad electrode of the non-active area NA, an area to dispose the gate driver GD and the pad electrode needs to be provided in the non-active area NA. By doing this, a bezel may be enlarged.

In contrast, if the gate driver GD is mounted in the active area AA in the GIA manner and a side line which connects the signal line on the front surface of the display panel PN to the pad electrode on a rear surface of the display panel PN is formed to bond the flexible film and the printed circuit board onto a rear surface of the display panel PN, the non-active area NA on the front surface of the display panel PN may be minimized or reduced. That is, if the gate driver GD, the data driver DD, and the timing controller TC are connected to the display panel PN as described above, a zero or near zero bezel with substantially no bezel may be implemented.

A plurality of sub pixels SP may form one pixel. Further, the plurality of sub pixels SP may be configured by sub pixels SP for emitting different color lights. For example, the plurality of sub pixels SP may include a red sub pixel, a green sub pixel, and a blue sub pixel. However, the present disclosure is not limited thereto, and the plurality of sub pixels SP may further include a sub pixel SP which emits a different color light.

At least some of the plurality of sub pixels SP may include two light emitting diodes, respectively. Here, two light emitting diodes may emit the same color light. For example, two light emitting diodes which emit red light may be disposed in the red sub pixel, two light emitting diodes which emit green light may be disposed in the green sub pixel, and two light emitting diodes which emit blue light may be disposed in the blue sub pixel.

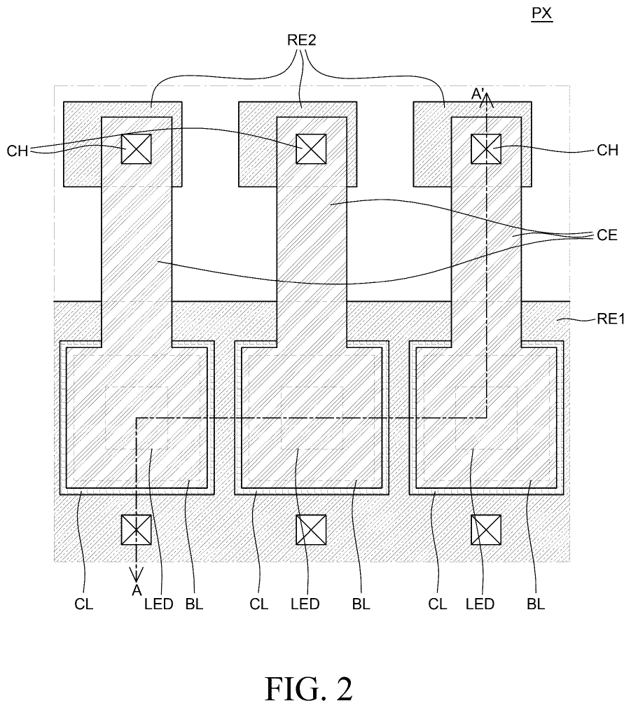

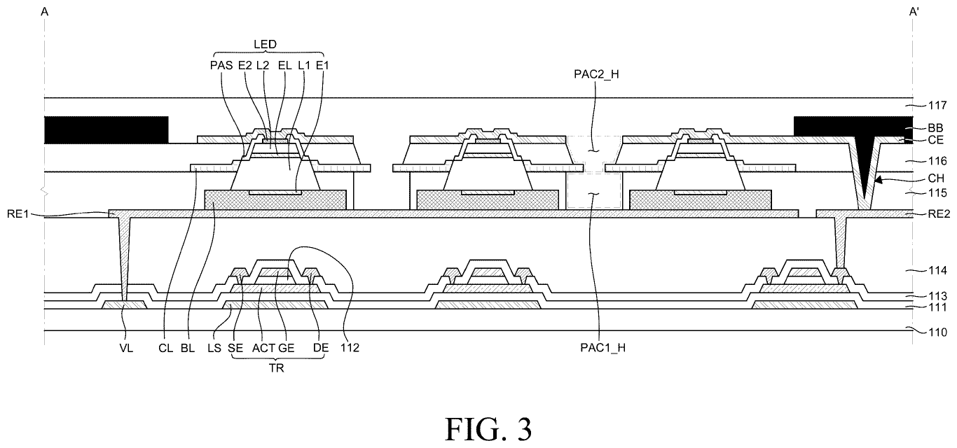

FIG. 2 is a plan view of a pixel of a display device according to an example embodiment of the present disclosure. FIG. 3 is a cross-sectional view along line A-A′ in FIG. 2. For example, FIG. 2 is an enlarged plan view of a part of a pixel PX of the display device 100 according to an example embodiment of the present disclosure. Further, FIG. 3 is a cross-sectional view of a pixel PX of the display device 100 according to an example embodiment of the present disclosure.

As shown in FIGS. 2 and 3 together, the display device 100 according to the example embodiment of the present disclosure includes a substrate 110, a buffer layer 111, a gate insulating layer 112, an interlayer insulating layer 113, a first planarization layer 114, a second planarization layer 115, a third planarization layer 116, a fourth planarization layer 117, a transistor TR, a plurality of light emitting diodes LED, a plurality of bonding layers BL, a plurality of conductive layers CL, a plurality of reflection electrodes RE (e.g., RE1, RG2), a power line VL, a connection electrode CE, and a black bank BB.

First, the substrate 110 is a component for supporting various components included in the display device 100 and may be formed of an insulating material. For example, the substrate 110 may be formed of glass or resin. Further, the substrate 110 may be configured to include a polymer or plastic or may be formed of a material having flexibility.

A light shielding layer LS may be disposed on the substrate 110. The light shielding layer LS blocks light from being incident onto an active layer ACT of the transistor TR (to be described below) from a lower portion of the substrate 110. Light transmitting toward the active layer ACT of the transistor TR is blocked by the light shielding layer LS to minimize or reduce a leakage current.

Further, the power line VL may be disposed on the substrate 110. Specifically, the power line VL may be disposed to be spaced apart from the light shielding layer LS on the same layer as the light shielding layer LS. Further, the power line VL may be formed of the same material as the light shielding layer LS but is not limited thereto. In the display device 100 according to the example embodiment of the present disclosure, the power line VL may be a low potential power line and may be supplied with a low potential voltage, but is not limited thereto. The power line VL may be a high potential power line to which a high potential voltage is supplied.

The buffer layer 111 may be disposed on the power line VL and the light shielding layer LS. The buffer layer 111 may reduce permeation of moisture or impurities through the substrate 110. The buffer layer 111 may be configured by a single layer or multiple layers of silicon oxide (SiOx) or silicon nitride (SiNx), but is not limited thereto. However, the buffer layer 111 may be omitted depending on a type of substrate 110 or a type of transistor TR, but is not limited thereto. The buffer layer 111 may include a contact hole (to be described below) through which the first reflection electrode RE1 and the power line VL are connected.

A plurality of transistors TR may be disposed on the buffer layer 111. A transistor TR may include an active layer ACT, a gate electrode GE, a source electrode SE, and a drain electrode DE.

The active layer ACT may be disposed on the buffer layer 111. The active layer ACT may be formed of a semiconductor material, such as an oxide semiconductor, amorphous silicon, or polysilicon, but is not limited thereto.

The gate insulating layer 112 may be disposed on the active layer ACT. The gate insulating layer 112 is an insulating layer for insulating the active layer ACT from the gate electrode GE. Therefore, the gate insulating layer 112 may be disposed only between the gate electrode GE and the active layer ACT, but is not limited thereto. For example, a maximum width of the gate insulating layer 112 may be smaller than a maximum width of the active layer ACT. Further, the gate insulating layer 112 may completely overlap the active layer ACT on the active layer ACT. Further, the gate insulating layer 112 may be spaced apart from the source electrode SE and the drain electrode DE (to be described below). For example, the gate insulating layer 112 may be configured by a single layer or multiple layers of silicon oxide (SiOx) or silicon nitride (SiNx), but is not limited thereto.

The gate electrode GE may be disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 may be disposed on the gate insulating layer 112. The interlayer insulating layer 113 may include a contact hole for connecting the source electrode SE and the active layer ACT. Further, the interlayer insulating layer 113 may include another contact hole for connecting the drain electrode DE and the active layer ACT. The interlayer insulating layer 113 is an insulating layer which protects components below the interlayer insulating layer 113 and may be configured by a single layer or multiple layers of silicon oxide SiOx or silicon nitride SiNx, but is not limited thereto.

The source electrode SE and the drain electrode DE electrically connected to the active layer ACT may be disposed on the interlayer insulating layer 113. The source electrode SE and the drain electrode DE may be disposed on the same layer to be spaced apart from each other. The source electrode SE may be connected to the active layer ACT through a contact hole included in the interlayer insulating layer 113. The drain electrode DE may be connected to the active layer ACT through another contact hole included in the interlayer insulating layer 113. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

The first planarization layer 114 may be disposed on the source electrode SE and the drain electrode DE. The first planarization layer 114 may planarize an upper portion of the pixel circuit including the transistor TR. The first planarization layer 114 may be configured by a single layer or multiple layers, and for example, configured by benzocyclobutene or an acrylic-based organic material, but is not limited thereto.

A plurality of reflection electrodes RE may be disposed on the first planarization layer 114. Further, the plurality of reflection electrodes RE may include a first reflection electrode RE1 and a second reflection electrode RE2. The first reflection electrode RE1 and the second reflection electrode RE2 may be spaced apart from each other. In the display device 100 according to the example embodiment of the present disclosure, a single first reflection electrode RE1 overlaps all the plurality of light emitting diodes LED in one pixel PX. A plurality of second reflection electrodes RE2 may be provided to correspond to the number of the plurality of light emitting diodes LED provided. Here, the plurality of second reflection electrodes RE2 may be spaced apart from the plurality of light emitting diodes LED. Further, the plurality of second reflection electrodes RE2 may be spaced apart from each other.

The first reflection electrode RE1 may be connected to the power line VL via a contact hole through the first planarization layer 114, the interlayer insulating layer 113, and the buffer layer 111. Further, the first reflection electrode RE1 may be in contact with the plurality of bonding layers BL (to be described below). Therefore, the first reflection electrode RE1 may electrically connect the power line VL and the plurality of bonding layers BL (to be described below) and the plurality of light emitting diodes LED.

The plurality of second reflection electrodes RE2 may be connected to the plurality of transistors TR, respectively, through contact holes in the first planarization layer 114. For example, the plurality of second reflection electrodes RE2 may be connected to drain electrodes DE of the plurality of transistors TR, respectively, but is not limited thereto. Further, the second reflection electrodes RE2 may be electrically connected to the second electrodes E2 of the plurality of light emitting diodes LED respectively through the plurality of connection electrodes CE (to be described below).

The first reflection electrode RE1 and the second reflection electrode RE2 may include various conductive layers in consideration of a light reflection efficiency and resistance. For example, the first reflection electrode RE1 and the second reflection electrode RE2 may use an opaque conductive layer, such as silver (Ag), aluminum (Al), molybdenum (Mo), titanium (Ti), or an alloy thereof, and/or a transparent conductive layer, such as indium tin oxide (ITO), but are not limited thereto.

The plurality of bonding layers BL may be disposed on the first reflection electrode RE1. Further, the plurality of light emitting diodes LED may disposed on the plurality of bonding layers BL so as to correspond to the plurality of bonding layers BL, respectively. Therefore, the plurality of bonding layers BL may serve to fix the plurality of light emitting diodes LED (to be described below), respectively.

In the plan view, an area of a bonding layer BL may be larger than an area of a light emitting diode LED. In the cross-sectional view, a maximum width of the bonding layer BL may be larger than a maximum width of the light emitting diode LED. Therefore, the entirety of the light emitting diode LED may overlap the bonding layer BL. For example, the plurality of light emitting diodes LED may be disposed inside the bonding layers BL, in the plan view, so as not to be deviated from the bonding layers BL on the bonding layers BL. A planar shape of the bonding layer BL may correspond to a planar shape of the light emitting diode LED, but is not limited thereto.

In the plan view, at least some of the plurality of bonding layers BL may be disposed on the same row and be spaced apart from each other. For example, at least some of the plurality of bonding layers BL may be spaced apart from each other with the constant interval, but are not limited thereto. As another example, at least some of the plurality of bonding layers BL may be spaced apart from each other at different intervals.

The bonding layer BL may be disposed so as to enclose the side surface of the first electrode E1 of the light emitting diode LED. For example, the bonding layer BL may be disposed so as to enclose the entire side surface of the first electrode E1. Specifically, the bonding layer BL may include a concave portion on the top surface, and the first electrode E1 may be inserted into the concave portion of the bonding layer BL. The bonding layer BL may be in contact with a part of the bottom surface of the first semiconductor layer L1 of the light emitting diode LED, but is not limited thereto.

The bonding layer BL may include a conductive material and may further include a black material. Therefore, the bonding layer BL may be black. For example, the conductive material may include carbon. For example, the bonding layer BL may be formed by dispersing a conductive material including carbon in an acrylic resin, but is not limited thereto. As described above, the bonding layer BL includes a conductive material to electrically connect the first reflection electrode RE1 and the first electrode E1.

In one pixel PX, the plurality of light emitting diodes LED may emit different color lights. For example, in one pixel PX, the plurality of light emitting diodes LED may include a red light emitting diode which emits red light, a green light emitting diode which emits green light, and a blue light emitting diode which emits blue light.

In the plan view, at least some of the plurality of light emitting diodes LED may be disposed on the same row. Further, at least some of the plurality of light emitting diodes LED may be disposed to be spaced apart from each other with the same interval, but are not limited thereto. For example, at least some of the plurality of light emitting diodes LED may be disposed to be spaced apart from each other at different intervals.

A light emitting diode LED may include a first electrode E1, a first semiconductor layer L1, an emission layer EL, a second semiconductor layer L2, and a second electrode E2.

In the display device 100 according to the example embodiment of the present disclosure, the first electrode E1 may be a cathode electrode for injecting electrons to the emission layer EL. Further, the first electrode E1 may be a cathode electrode and may also serve as a reflection layer which upwardly reflects light emitted from the emission layer EL. The first electrode E1 may be configured by a conductive material, for example, a transparent conductive material, such as indium tin oxide (ITO) or indium zinc oxide (IZO), or a reflective conductive material, such as titanium (Ti), gold (Au), silver (Ag), copper (Cu) or an alloy thereof, but is not limited thereto.

The first semiconductor layer L1 is disposed on the first electrode E1. In the display device 100 according to the example embodiment of the present disclosure, the first semiconductor layer may be a layer formed by doping an n-type impurity. For example, the first semiconductor layer L1 may be a layer formed by doping an n-type impurity into a host material, such as gallium nitride (GaN), indium aluminum phosphide (InAlP), or gallium arsenide (GaAs). The n-type impurity may be silicon (Si), germanium, or tin (Sn), but is not limited thereto.

A width of the bottom surface of the first semiconductor layer L1 may be larger than a width of the top surface of the first electrode E1. Therefore, at least a part of the bottom surface of the first semiconductor layer L1 may be exposed by the first electrode E1. As described above, a part of the bottom surface of the first semiconductor layer L1 exposed may be bonded to the bonding layer BL.

In another aspect, the width of the bottom surface of the first semiconductor layer L1 may be equal to the width of the top surface of the first electrode E1. In this case, the bottom surface of the first semiconductor layer L1 is not in contact with the bonding layer BL. Therefore, the bottom surface and the side surface of the first electrode E1 may be bonded to the bonding layer BL to fix the light emitting diode LED.

The emission layer EL is disposed on the first semiconductor layer L1. The emission layer EL is supplied with holes and electrons from the first semiconductor layer L1 and the second semiconductor layer L2 to emit light. The emission layer EL may be formed by a single layer or a multi-quantum well (MQW) structure, and for example, may be formed of indium gallium nitride (InGaN), gallium arsenide (GaAs), or gallium nitride (GaN), but is not limited thereto.

The second semiconductor layer L2 is disposed on the emission layer EL. In the display device 100 according to the example embodiment of the present disclosure, the second semiconductor layer L2 may be a layer formed by doping a p-type impurity into a specific material. For example, the second semiconductor layer L2 may be a layer formed by doping a p-type impurity into a host material, such as gallium nitride (GaN), indium aluminum phosphide (InAlP), or gallium arsenide (GaAs). Here, the p-type impurity may be magnesium, zinc (Zn), or beryllium (Be), but is not limited thereto.

The second electrode E2 is disposed on the second semiconductor layer L2. In the display device 100 according to the example embodiment of the present disclosure, the second electrode E2 may be an anode electrode for injecting holes to the emission layer EL. The second electrode E2 may be configured by a conductive material, for example, a transparent conductive material, such as indium tin oxide (ITO) or indium zinc oxide (IZO), or an opaque conductive material, such as titanium (Ti), gold (Au), silver (Ag), copper (Cu) or an alloy thereof, but is not limited thereto.

A maximum width of the second electrode E2 may be smaller than a width of the top surface of the second semiconductor layer L2. Therefore, at least a part of the top surface of the second semiconductor layer L2 may be exposed by the second electrode E2.

Next, the encapsulation film PAS may be disposed to enclose at least a part of the first semiconductor layer L1, the emission layer EL, the second semiconductor layer L2, and the second electrode E2.

The encapsulation film PAS may be formed of an insulating material to protect the first semiconductor layer L1, the emission layer EL, and the second semiconductor layer L2. Further, in the encapsulation film PAS, a contact hole exposing the second electrode E2 may be formed to electrically connect the connection electrode CE (to be described below) and the second electrode E2.

The second planarization layer 115 may be disposed on the plurality of bonding layers BL. The second planarization layer 115 may planarize upper portions of the first reflection electrode RE1, the second reflection electrode RE2, and the plurality of bonding layers BL disposed therebelow.

The second planarization layer 115 may cover at least a part of the first reflection electrode RE1, the second reflection electrode RE2, and the plurality of bonding layers BL. For example, the second planarization layer 115 may cover at least a part of top surfaces of the plurality of bonding layers BL. Further, the second planarization layer 115 may cover the entire side surfaces of the plurality of bonding layers BL. Therefore, the second planarization layer 115 may be disposed so as to enclose the plurality of bonding layers BL.

The second planarization layer 115 may be disposed so as to enclose a part of the plurality of light emitting elements LED. For example, the second planarization layer 115 may be disposed so as to enclose a part of side surfaces of the plurality of light emitting elements LED. Further, the second planarization layer 115 may be in contact with at least a part of the side surface of the first semiconductor layer L1 exposed by the encapsulation film PAS.

The second planarization layer 115 may include a plurality of first holes PAC1_H formed between the plurality of light emitting diodes LED. The second planarization layer 115 may include portions that are spaced apart between the plurality of light emitting diodes LED by the plurality of first holes PAC1_H. Therefore, the first reflection electrode RE1 may be exposed between the plurality of light emitting diodes LED by the plurality of first holes PAC1_H. Further, the second planarization layer 115 may further include a plurality of contact holes CH for respectively connecting the plurality of connection electrodes CE (to be described below) and the plurality of second reflection electrodes RE2.

A plurality of conductive layers CL is disposed on the second planarization layer 115. Here, the plurality of conductive layers CL may be disposed to protrude away from the side surfaces of the plurality of light emitting diodes LED. A conductive layer CL may be disposed to be in contact with the top surface of the second planarization layer 115. Further, the conductive layer CL may be in contact with the side surface of the light emitting diode LED. For example, the conductive layer CL may have its largest thickness at a part which is in contact with the side surface of the light emitting diode LED. Therefore, the top surface of the conductive layer CL may be formed by two areas having different heights. Further, the top surface of the conductive layer CL may include at least one step.

In the cross-sectional view, at least one end portion of the plurality of conductive layers CL may protrude farther outside than one end portion of the second planarization layer 115 does. Specifically, between the plurality of light emitting diodes LED, one end portion of the plurality of conductive layers CL may protrude farther outside than one end portion of the second planarization layer 115 does. Therefore, between the plurality of light emitting diodes LED, the second planarization layer 115 may form an undercut structure by the plurality of conductive layers CL which protrudes farther outside.

Further, the end of the conductive layer CL may protrude farther outside than the end of the bonding layer BL does. Therefore, in the plan view, an outline of the conductive layer CL may have a shape which encloses an outline of the bonding layer BL. Unless otherwise specified in this specification, the outside means the direction away from the light emitting diode LED, and the inside means the direction closer to the light emitting diode LED.

The plurality of conductive layer CLs are spaced apart from each other. Specifically, the plurality of conductive layers CL are spaced apart from each other at the first hole PAC1_H formed between the plurality of light emitting diodes LED. Therefore, at least a part of the first reflection electrode RE1 may be exposed by the plurality of conductive layers CL which are spaced apart from each other.

The plurality of conductive layers CL may include a conductive material, for example, a transparent conductive material, such as indium tin oxide (ITO) or indium zinc oxide (IZO), or a reflective metal material, but is not limited thereto. The plurality of conductive layers CL may be configured by a single layer or multiple layers of silicon oxide (SiOx) or silicon nitride (SiNx) which is an inorganic film.

The third planarization layer 116 may be disposed on the plurality of conductive layers CL. The third planarization layer 116 may be in contact with at least a part of top surfaces of the plurality of conductive layers CL. Therefore, the plurality of conductive layers CL may be disposed between the second planarization layer 115 and the third planarization layer 116. Further, the third planarization layer 116 may cover an end of at least some of the plurality of conductive layers CL. Further, the third planarization layer 116 may cover uppermost edges of the plurality of conductive layers CL. Together with this, the third planarization layer 116 may be in contact with at least a part of side surfaces of the plurality of light emitting elements LED. Further, the third planarization layer 116 may be disposed so as to enclose a part of the plurality of light emitting elements LED. Therefore, the third planarization layer 116 may fix and protect the plurality of light emitting diodes LED.

The third planarization layer 116 may include a second hole PAC2_H between the plurality of light emitting diodes LED. The third planarization layer 116 may include portions that are spaced apart from each other between the plurality of light emitting diodes LED by the second hole PAC2_H. The second hole PAC2_H may overlap the first hole PAC1_H. Further, the second hole PAC2_H may overlap an area in which the plurality of conductive layers CL is spaced apart from each other. Therefore, the first reflection electrode RE1 may be exposed between the plurality of light emitting diodes LED.

One end portion of the third planarization layer 116 may be disposed farther inside from one end portion of the plurality of conductive layers CL between the plurality of light emitting diodes LED. Therefore, between the plurality of light emitting diodes LED, one ends of the plurality of conductive layers CL may protrude farther outside than one ends of the second planarization layer 115 and the third planarization layer 116 do. The side surface of the third planarization layer 116 may be slanted so that the lower portion outwardly protrudes farther than the upper portion. Therefore, the third planarization layer 116 may have a taper shape, and the second hole PAC2_H may have an inverted taper shape, but they are not limited thereto.

The third planarization layer 116 may further include a contact hole CH for connecting the connection electrode CE (to be described below) and the second reflection electrode RE2. Here, the contact hole CH in the third planarization layer 116 is connected to or aligned with the contact hole CH in the second planarization layer 115 to form one contact hole CH.

For example, the first planarization layer 114, the second planarization layer 115, and the third planarization layer 116 may be configured by benzocyclobutene or an acrylic-based organic material, but are not limited thereto. The first planarization layer 114, the second planarization layer 115, and the third planarization layer 116 may be formed of different materials from one another, but are not limited thereto and may be formed of the same material.

In the display device 100 according to the example embodiment of the present disclosure, a plurality of connection electrodes CE is disposed on the third planarization layer 116. The plurality of connection electrodes CE may electrically connect the plurality of light emitting diodes LED and the plurality of second reflection electrodes RE2, respectively. For example, one second reflection electrode RE2 and one light emitting diode LED may be electrically connected through one connection electrode CE.

One end portions of the plurality of connection electrodes CE are respectively connected to the plurality of light emitting diodes LED, and the other end portions are respectively connected to the plurality of second reflection electrodes RE2 through a contact hole CH. As described above, the connection electrodes CE may be connected respectively to the second reflection electrodes RE2 through corresponding contact holes CH in the second planarization layer 115 and the third planarization layer 116. Further, a connection electrode CE may be connected to the corresponding second electrode E2 exposed by the encapsulation film PAS. Therefore, the connection electrode CE may electrically connect the drain electrode DE of the corresponding transistor TR and the second electrode E2 of the corresponding light emitting diode LED.

Ends of the plurality of connection electrodes CE may be disposed farther inside from ends of the plurality of conductive layers CL. Further, the plurality of connection electrodes CE may be spaced apart from each other. Specifically, the plurality of connection electrodes CE may be disposed so as to correspond to the plurality of light emitting diodes LED, respectively, and may be spaced apart from each other between the plurality of light emitting diodes LED. The plurality of connection electrodes CE do not overlap the second hole PAC2_H.

The connection electrodes CE may be configured by a conductive material, for example, a transparent conductive material, such as indium tin oxide (ITO) or indium zinc oxide (IZO), or an opaque conductive material, such as titanium (Ti), gold (Au), silver (Ag), copper (Cu) or an alloy thereof, but is not limited thereto.

The black bank BB may be disposed on the third planarization layer 116 and the plurality of connection electrodes CE. The black bank BB is a component for distinguishing adjacent sub pixels SP. The black bank BB may be disposed so as not to overlap the emission layers EL of the light emitting diodes LED. The black bank BB may cover one end portion of the connection electrode CE. Therefore, the black bank BB may cover at least a part of the top surface of the connection electrode CE. Further, the black bank BB may fill a space in the contact hole CH above the connection electrode CE.

The black bank BB may be formed of acrylic-based resin, benzocyclobutene (BCB)-based resin, or polyimide and may further include a black component, but is not limited thereto.

The fourth planarization layer 117 may be disposed on the black bank BB. The fourth planarization layer 117 covers the third planarization layer 116, the plurality of connection electrodes CE, and the black bank BB to protect configurations disposed therebelow. Further, the fourth planarization layer 117 may fill the first hole PAC1_H and the second hole PAC2_H. Therefore, the fourth planarization layer 117 may be in contact with a top surface of the first reflection electrode RE1 exposed by the first hole PAC1_H and the second hole PAC2_H between the plurality of light emitting diodes LED. Further, the fourth planarization layer 117 may fill the first hole PAC1_H between the plurality of bonding layers BL to allow the plurality of bonding layers BL to be completely spaced apart from each other.

The fourth planarization layer 117 may be configured by a single layer or multiple layers, and for example, may be formed of a photo resist or an acrylic-based organic material, but is not limited thereto.

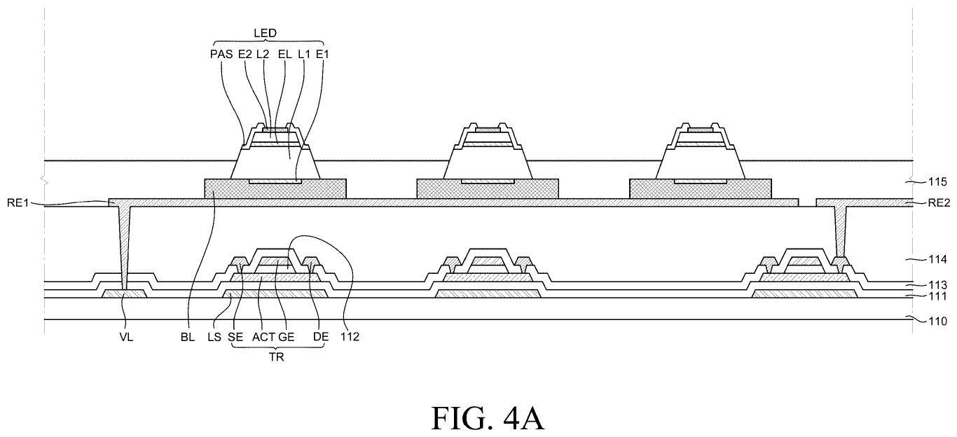

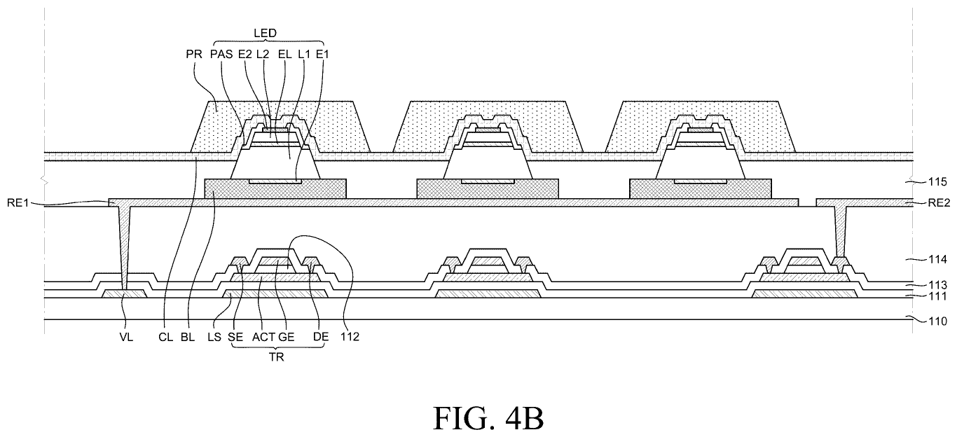

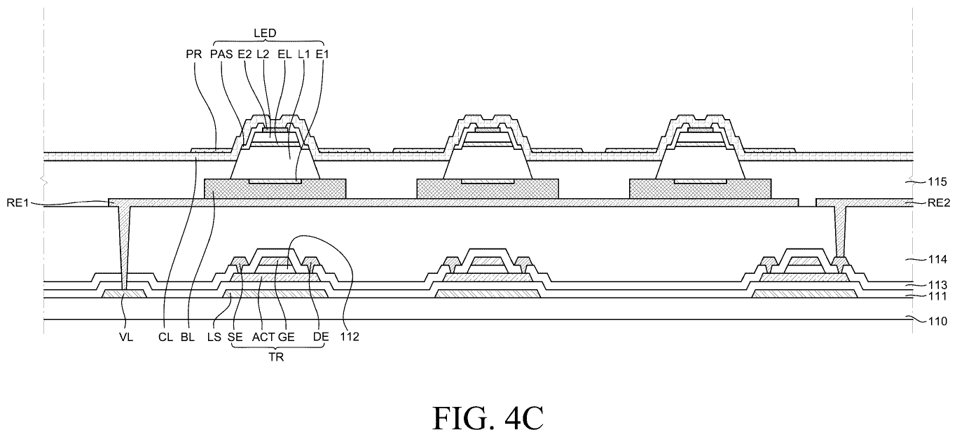

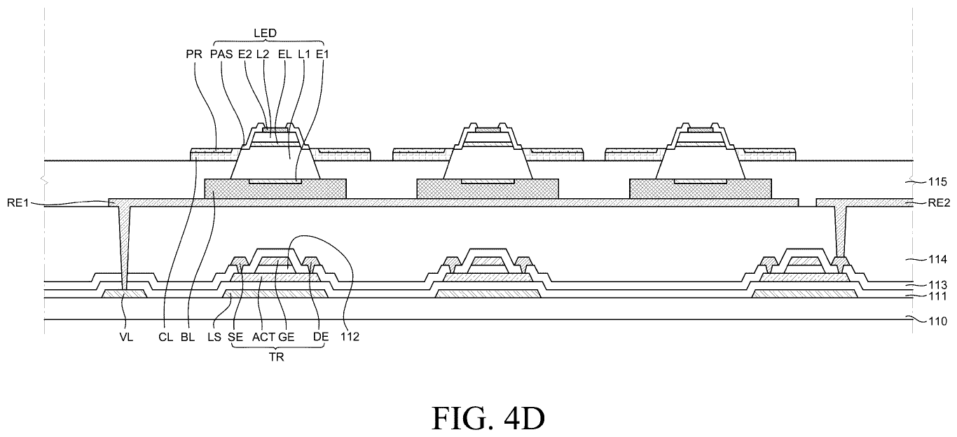

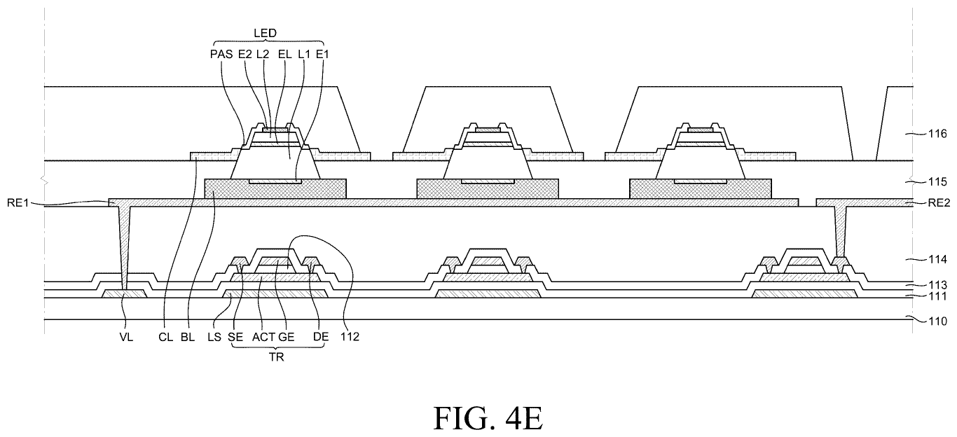

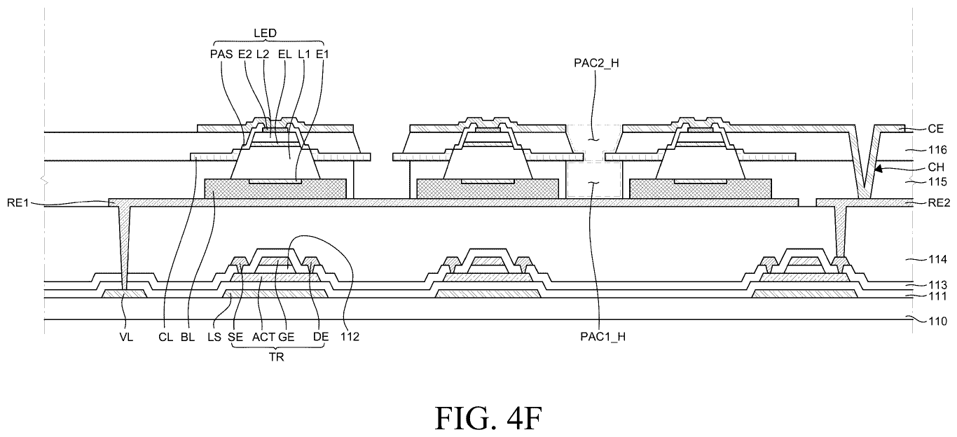

Hereinafter, a manufacturing method of a display device 100 according to an example embodiment of the present disclosure will be described in detail with reference to FIGS. 4A to 4F.

FIGS. 4A to 4F are process diagrams for explaining a manufacturing method of a pixel of a display device according to an example embodiment of the present disclosure.

First, as shown in FIG. 4A, the first reflection electrode RE1 and the second reflection electrode RE2 may be disposed on the substrate 110. Next, a bonding material for forming a plurality of bonding layers BL is applied on the first reflection electrode RE1. At this time, the bonding material may include a conductive material. Further, the applied bonding material is patterned to form the plurality of bonding layers BL. As described above, in the display device 100 according to the example embodiment of the present disclosure, the plurality of bonding layers BL do not include conductive balls, so that the size of each of the plurality of bonding layers BL may be reduced more. Therefore, the entire size of the pixel PX including the plurality of bonding layers BL may be reduced. Further, as described above, the size of the pixel PX is reduced so that more pixels PX may be disposed in the same area to implement the display device 100 with a high resolution.

Next, the plurality of light emitting diodes LED may be transferred onto each of the plurality of formed bonding layers BL. At this time, the first electrode E1 of each of the plurality of light emitting diodes LED may be inserted into the bonding layer BL to be bonded. Further, each of the plurality of bonding layers BL may be formed to be wider than each of the plurality of light emitting diodes LED. Therefore, even if an alignment error occurs during the process of transferring the plurality of light emitting diodes LED, the plurality of light emitting diodes LED may be stably transferred onto the plurality of bonding layers BL. Next, a material for forming the second planarization layer 115 may be applied. At this time, a height of a top surface of the second planarization layer 115 may be formed to be higher than top surfaces of the plurality of bonding layers BL. Further, the height of the top surface of the second planarization layer 115 may be formed to be lower than a height of the top surfaces of the plurality of light emitting diodes LED. Therefore, the second planarization layer 115 may be formed to cover the side surfaces and the top surfaces of the plurality of bonding layers BL. Further, a part of the side surface and the top surface of the plurality of light emitting diodes LED may be exposed by the second planarization layer 115.

Next, as shown in FIG. 4B, the conductive layer CL may be disposed on the second planarization layer 115 and the plurality of light emitting diodes LED exposed by the second planarization layer 115. Further, a photo resist PR for patterning a conductive layer CL may be disposed. At this time, the photo resist PR is patterned so as to cover each of the plurality of light emitting diodes LED. The plurality of patterned photo resists PR may be disposed on the conductive layer CL so as to cover a top surface and a side surface of each of the plurality of light emitting diodes LED. Therefore, a part of the conductive layer CL may be exposed by the plurality of photo resists PR.

Next, as shown in FIG. 4C, a process of etching a plurality of photo resists PR may be performed. As described above, the plurality of photo resists PR are etched so that a height of top surfaces of the plurality of photo resists PR is lower than a height of top surfaces of the plurality of light emitting diodes LED. Therefore, a part of the conductive layer CL covering the top surfaces and a part of the side surfaces of the plurality of light emitting diodes LED may be exposed by the plurality of etched photo resists PR.

Next, as shown in FIG. 4D, a process of etching a conductive layer CL exposed by the plurality of photo resists PR may be performed. Therefore, the conductive layer CL in an area not covered by the plurality of photo resists PR may be removed. Further, the conductive layer CL may be maintained only in a partial area which is in contact with the side surfaces of the plurality of light emitting diodes LED.

Next, as shown in FIG. 4E, a material for forming the third planarization layer 116 may be applied on the second planarization layer 115, the conductive layer CL, and the light emitting diode LED. Further, a patterning process for removing portions of the third planarization layer 116 between the plurality of light emitting diodes LED may be performed. Therefore, portions of the third planarization layer 116 between the plurality of light emitting diodes LED may be removed. At this time, ends of the third planarization layer 116 between the plurality of light emitting diodes LED may be located respectively on the plurality of conductive layers CL. Therefore, a part of the top surface of the second planarization layer 115 may be exposed between the plurality of light emitting diodes LED.

Next, as shown in FIG. 4F, an etching process of a third planarization layer 116 may be performed. The height of the top surface of the third planarization layer 116 is lowered by the etching process so that the top surfaces of the plurality of light emitting diodes LED may be exposed. The second planarization layer 115 exposed between the plurality of light emitting diodes LED may be etched together by means of the etching process of the third planarization layer 116. Therefore, between the plurality of light emitting diodes LED, the first hole PAC1_H may be formed in the second planarization layer 115, and the second hole PAC2_H may be formed in the third planarization layer 116. At this time, the plurality of conductive layers CL are not etched by an etchant used for etching the third planarization layer 116 so that the plurality of conductive layers CL may serve as a pattern mask. Accordingly, portions of the second planarization layer 115 not covered by the plurality of conductive layers CL between the plurality of light emitting diodes LED may be removed. Further, a part of the etchant may permeate to lower portions of the plurality of conductive layers CL so that a part of the portions of the second planarization layer 115 covered by the plurality of conductive layers CL may also be removed. Accordingly, the conductive layer CL and the second planarization layer 115 may form an undercut structure in the first hole PAC1_H between the plurality of light emitting diodes LED.

Next, the plurality of connection electrodes CE may be disposed respectively on the plurality of light emitting diodes LED exposed by the third planarization layer 116. At this time, the plurality of connection electrodes CE may be disposed respectively to completely cover the top surfaces of the plurality of light emitting diodes LED exposed by the third planarization layer 116. Further, the plurality of connection electrodes CE may be disposed so as to correspond respectively to the plurality of light emitting diodes LED. At this time, because the plurality of connection electrodes CE may apply different signals respectively to the plurality of light emitting diodes LED, the plurality of connection electrodes CE are completely separated from each other. However, sizes of the light emitting diodes are reduced more for a high resolution display device, and an interval therebetween is reduced so that a space for separating the connection electrodes may become smaller. Therefore, during the patterning process for separating the connection electrodes, a patterning defect may occur where the adjacent connection electrodes are not completely separated from each other. As described above, when the patterning defect occurs, a short-circuit defect may occur where the adjacent connection electrodes are electrically connected to each other. However, in the display device 100 according to the example embodiment of the present disclosure, the connection electrodes CE are disposed after forming the undercut structure of the second planarization layer 115 between the plurality of light emitting diodes LED. Therefore, the connection electrodes CE may be completely disconnected from each other between the plurality of light emitting diodes LED.

Specifically, the light emitting diode LED is a semiconductor light emitting diode which converts current into light and is used to implement various display devices. To implement a high resolution in the display device, more pixels are disposed in a limited space. Therefore, for a higher resolution, the size of the pixel is smaller, and the light emitting diodes disposed in the sub pixels in the pixel are also smaller-sized.

As described above, as the light emitting diodes become smaller-sized and more densely formed, connection electrodes applying different signals respectively to the light emitting diodes are to be more precisely patterned. Specifically, in the case of a p-up structure in which the anode electrode of the light emitting diode is disposed on an upper portion, the anode electrode of each of the plurality of light emitting diodes is connected to a corresponding one of the plurality of transistors. Therefore, a display device with a p-up structure may include a plurality of connection electrodes which electrically connect anode electrodes of the plurality of light emitting diode and the plurality of transistors, respectively. Here, the plurality of light emitting diodes emit different colors so that the plurality of connection electrodes apply different signals to the plurality of light emitting diodes, respectively. Accordingly, the connection electrodes are patterned to be spaced apart from each other so as to correspond respectively to the plurality of light emitting diodes.

Here, during the process of transferring the light emitting diode, a misalignment defect may occur in which the light emitting diode is not transferred in a desired position. As described above, a connection electrode to be connected to the light emitting diode may be patterned to be disposed wider than the light emitting diode in consideration of a potential defect that the light emitting diode may be erroneously aligned. However, to implement a high resolution of the display device, it is difficult to ensure a sufficient space for spacing the connection electrodes patterned to be disposed in a wider area than the light emitting diodes in a situation where the light emitting diodes are small-sized and are densely disposed. As described above, if a sufficient space is not ensured between the plurality of connection electrodes, a patterning process for spacing the plurality of connection electrodes would need to be more precisely performed so that a probability of defects may increase. If a patterning defect occurs during the formation process of the connection electrodes, a residual of the connection electrodes due to the patterning defect may remain in the area between the plurality of light emitting diodes. Therefore, the plurality of connection electrodes to be spaced apart from each other may become electrically connected so that a short-circuit defect may occur.

Accordingly, the display device 100 according to the example embodiment of the present disclosure includes a plurality of conductive layers CL which protrude respectively from the side surfaces of the plurality of light emitting diodes LED to the outside and are spaced apart from each other. The plurality of conductive layers CL may serve as a pattern mask which suppresses the etching of the second planarization layer 115 disposed therebelow. The portions of the second planarization layer 115 not blocked by the plurality of conductive layer CL between the plurality of light emitting diodes LED may be removed, and a part of the portions of the second planarization layer 115 blocked by the plurality of conductive layer CL may not be removed. The second planarization layer 115 includes a plurality of first holes PAC1_H with an undercut structure between the plurality of light emitting diodes LED. Therefore, the plurality of connection electrodes CE disposed to correspond to the plurality of light emitting diodes LED, respectively, may be completely disconnected from each other between the plurality of light emitting diodes LED by the undercut structure of the second planarization layer 115.

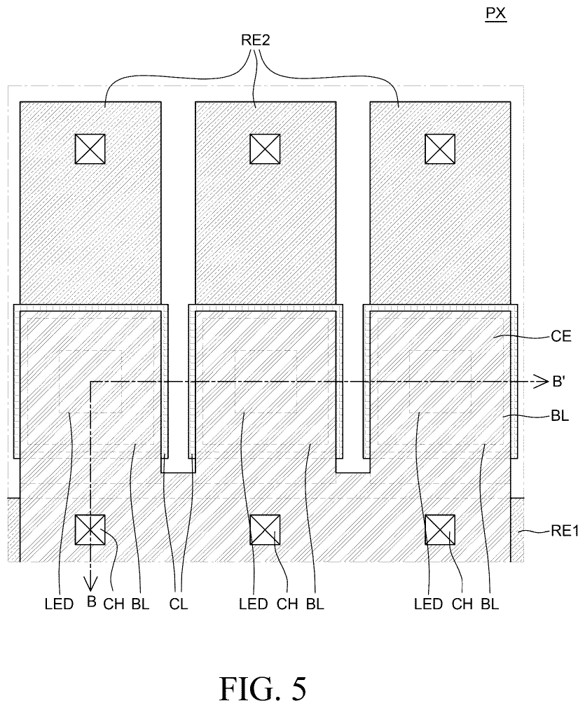

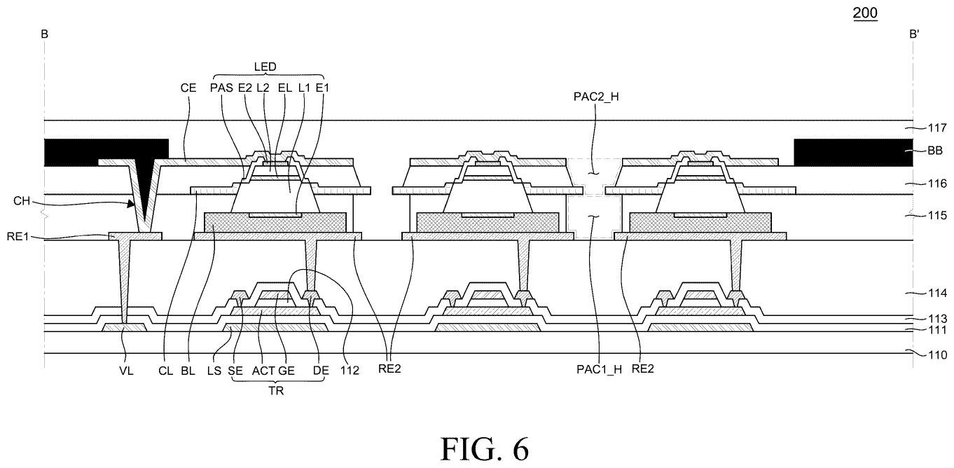

FIG. 5 is a plan view of a pixel of a display device according to another example embodiment of the present disclosure. FIG. 6 is a cross-sectional view along line B-B′ in FIG. 5. The example display device 200 of FIGS. 5 and 6 has the substantially same configurations as the example display device 100 of FIGS. 1 to 4G, except for a power line VL, a plurality of light emitting diodes LED, a plurality of reflection electrodes RE, and a connection electrode CE, so that a redundant description may be omitted.

As shown in FIGS. 5 and 6 together, in the display device 200 according to another example embodiment of the present disclosure, in one pixel PX, a single first reflection electrode RE1 is spaced apart from the plurality of light emitting diodes LED. Further, a plurality of second reflection electrodes RE2 may be disposed to be spaced apart from each other in a number corresponding to the number of the light emitting diodes LED. Further, the plurality of second reflection electrodes RE2 may overlap the plurality of light emitting diodes LED, respectively. For example, only one light emitting diode LED may be disposed on one second reflection electrode RE2.

The first reflection electrode RE1 may be connected to the power line VL via a contact hole through the first planarization layer 114, the interlayer insulating layer 113, and the buffer layer 111. In the display device 200 according to another example embodiment of the present disclosure, the power line VL may be a high potential power line and may be supplied with a high potential voltage, but is not limited thereto. The power line VL may instead be a low potential power line to which a low potential voltage is supplied. Further, the first reflection electrode RE1 may be connected to each of the plurality of light emitting diodes LED in one pixel PX through the connection electrode CE. For example, the plurality of light emitting diodes LED in one pixel PX may be electrically connected to one first reflection electrode RE1.

The plurality of second reflection electrodes RE2 may be spaced apart from the first reflection electrode RE1. Further, the plurality of second reflection electrodes RE2 may be disposed to be spaced apart from each other. Specifically, in the display device 200 according to another example embodiment of the present disclosure, the plurality of second reflection electrodes RE2 which respectively overlap the plurality of light emitting diodes LED may be disposed to be spaced apart from each other between the plurality of light emitting diodes LED. Further, in the display device 200 according to another example embodiment of the present disclosure, the plurality of second reflection electrodes RE2 are spaced apart from each other between the plurality of light emitting diodes LED at an area overlapping the first hole PAC1_H Therefore, the area where the plurality of second reflection electrodes RE2 are spaced apart from each other between the plurality of light emitting diodes LED may overlap the second hole PAC2_H. A part of the top surface of the first planarization layer 114 may be exposed between the plurality of light emitting diodes LED, by the plurality of second reflection electrodes RE2 which are spaced apart from each other.

The plurality of second reflection electrodes RE2 may be disposed so as to correspond to the plurality of bonding layers BL, respectively. Further, the second reflection electrodes RE2 may overlap the plurality of bonding layers BL, respectively. Here, the plurality of second reflection electrodes RE2 may be in contact with the plurality of bonding layers BL, respectively. Further, the plurality of second reflection electrodes RE2 may be connected to the drain electrodes DE of the plurality of transistors TR, respectively. Therefore, the plurality of light emitting diodes LED may be electrically connected to the plurality of transistors TR respectively by the plurality of second reflection electrodes RE2 correspondingly disposed.

In the display device 200 according to another example embodiment of the present disclosure, the first electrode E1 of the light emitting diode LED may be an anode electrode for injecting holes to the emission layer EL. Further, the first electrode E1 may be an anode electrode and may also serve as a reflection layer which upwardly reflects light emitted from the emission layer EL. The first electrode E1 may be configured by a conductive material, for example, a transparent conductive material, such as indium tin oxide (ITO) or indium zinc oxide (IZO), or an opaque conductive material, such as titanium (Ti), gold (Au), silver (Ag), copper (Cu) or an alloy thereof, but is not limited thereto.

Further, the first semiconductor layer L1 may be a layer formed by doping a p-type impurity into a specific host material. For example, the first semiconductor layer L1 may be a layer formed by doping a p-type impurity into a host material, such as gallium nitride (GaN), indium aluminum phosphide (InAlP), or gallium arsenide (GaAs). Here, the p-type impurity may be magnesium, zinc (Zn), or beryllium (Be), but is not limited thereto.

Further, the second semiconductor layer L2 may be a layer formed by doping an n-type impurity. For example, the second semiconductor layer L2 may be a layer formed by doping an n-type impurity into a host material, such as gallium nitride (GaN), indium aluminum phosphide (InAlP), or gallium arsenide (GaAs). The n-type impurity may be silicon (Si), germanium, or tin (Sn), but is not limited thereto.

Next, the second electrode E2 may be a cathode electrode for injecting electrons to the emission layer EL. Further, the second electrode E2 may be a cathode electrode and may also serve as a reflection layer which upwardly reflects light emitted from the emission layer EL. The first electrode E1 may be configured by a conductive material, for example, a transparent conductive material, such as indium tin oxide (ITO) or indium zinc oxide (IZO), or a reflective conductive material, such as titanium (Ti), gold (Au), silver (Ag), copper (Cu) or an alloy thereof, but is not limited thereto.

In the display device 200 according to another example embodiment of the present disclosure, one connection electrode CE may be provided in one pixel PX. Further, the one connection electrode CE may be connected to the plurality of light emitting diodes LED. Specifically, one connection electrode CE may be connected to the second electrodes E2 of the plurality of light emitting diodes LED. The connection electrode CE may be connected to the first reflection electrode RE1 through the contact hole CH in the second planarization layer 115 and the third planarization layer 116. Therefore, the connection electrode CE may electrically connect the plurality of light emitting diodes LED and the first reflection electrode RE1. As described above, the plurality of light emitting diodes LED may be electrically connected to the power line VL through the connection electrode CE and the first reflection electrode RE1.

Here, the connection electrode CE may not be disposed in areas between the plurality of light emitting diodes LED. Therefore, one connection electrode CE may have gaps between the plurality of light emitting diodes LED. Here, at least a part of an area in which the connection electrode CE has a gap may overlap an area in which the plurality of second reflection electrodes RE2 are spaced apart from each other.

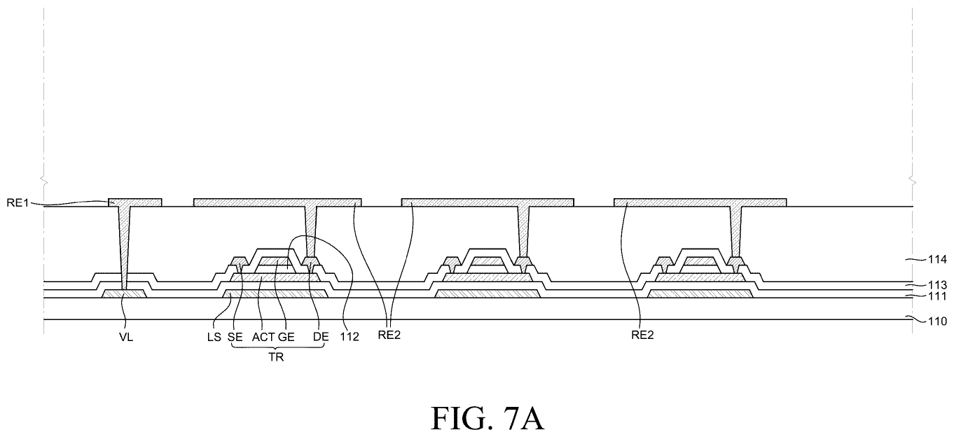

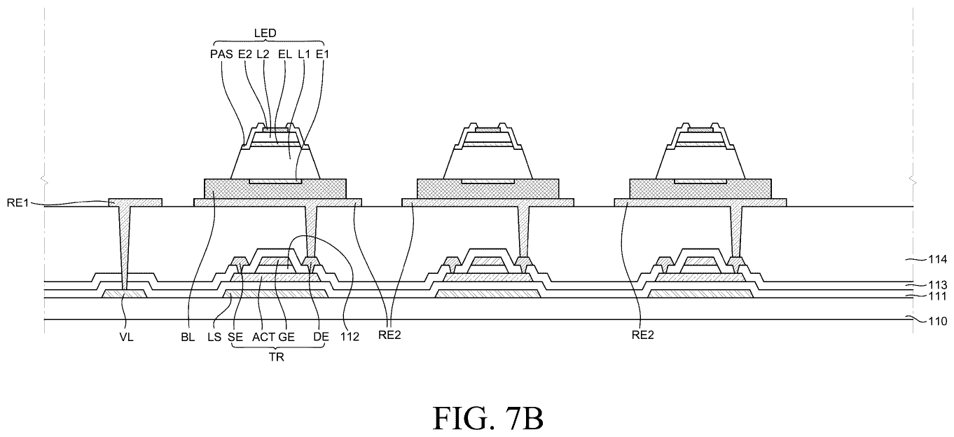

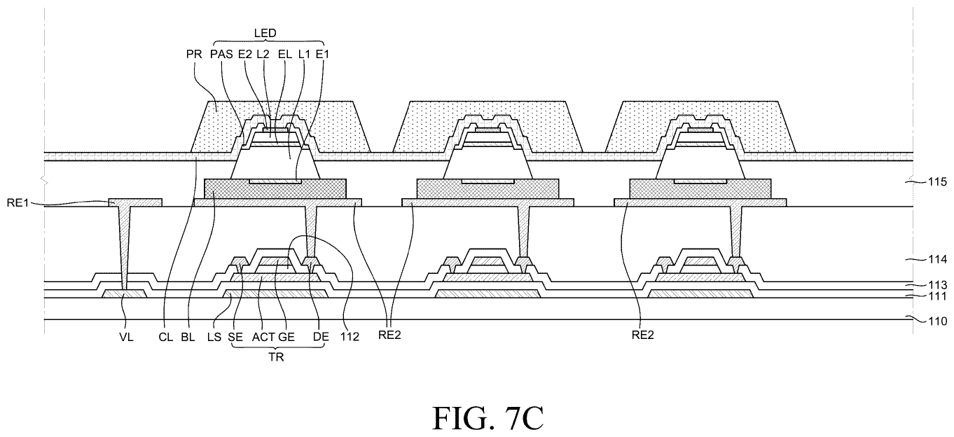

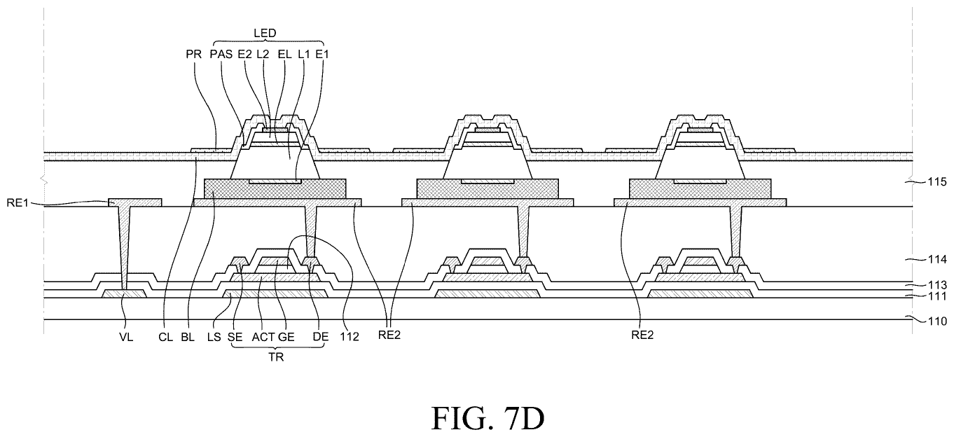

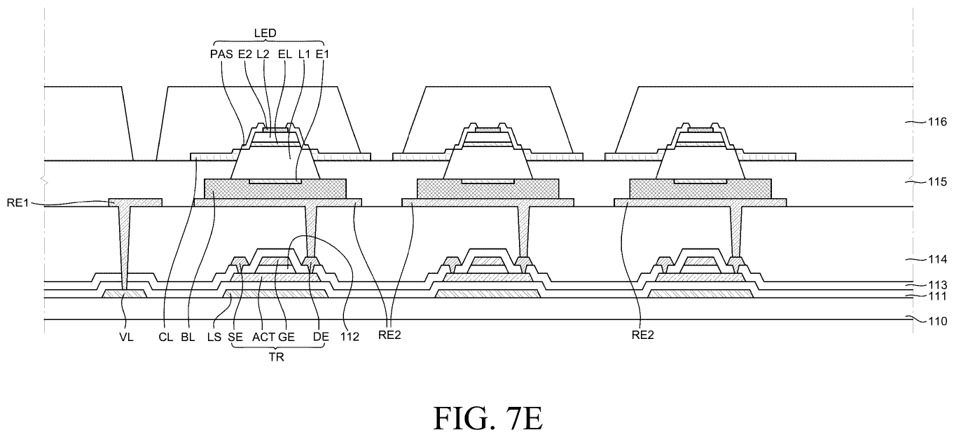

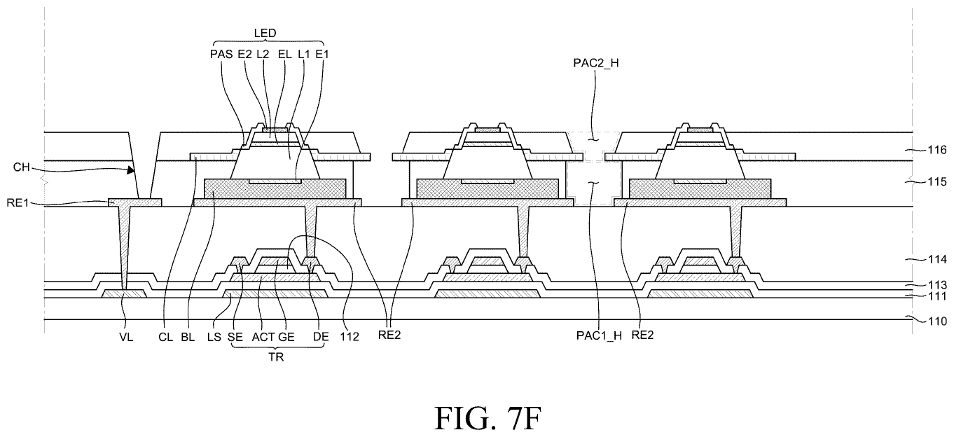

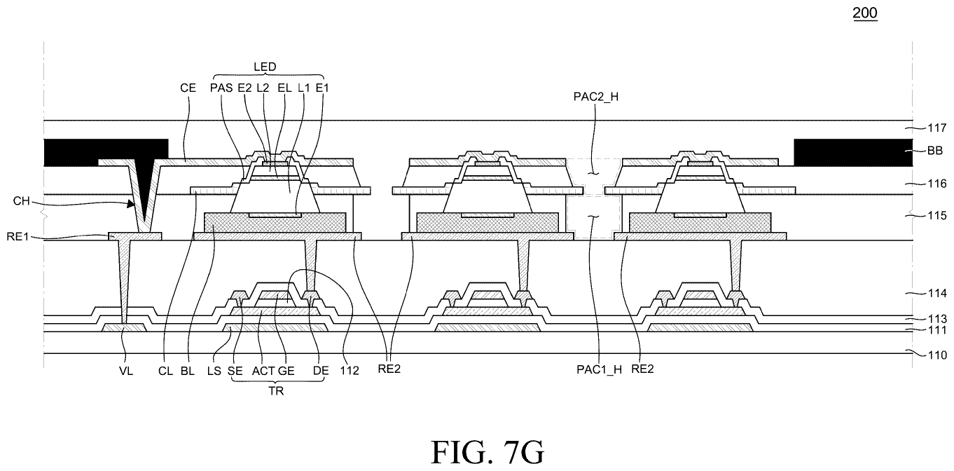

Hereinafter, a manufacturing method of a display device 200 according to another example embodiment of the present disclosure will be described in detail with reference to FIGS. 7A to 7G.

FIGS. 7A to 7G are process diagrams for explaining a manufacturing method of a pixel of a display device according to another example embodiment of the present disclosure.

First, as shown in FIG. 7A, a reflection electrode RE is disposed on a substrate 110 and is patterned to form a first reflection electrode RE1 and a plurality of second reflection electrodes RE2. At this time, the first reflection electrode RE1 and the plurality of second reflection electrodes RE2 may be disposed to be spaced apart from each other by the patterning process.

Next, as shown in FIG. 7B, a bonding material for forming the plurality of bonding layers BL may be applied on the first reflection electrode RE1 and the second reflection electrode RE2. At this time, the bonding material may include a conductive material. As described above, in the display device 200 according to another example embodiment of the present disclosure, the plurality of bonding layers BL does not include conductive balls, so that the size of each of the plurality of bonding layers BL may be reduced more. Therefore, the entire size of the pixel PX including the plurality of bonding layers BL may be reduced. Further, as described above, the size of the pixel PX is reduced so that more pixels PX may be disposed in the same area and that the display device 200 with a high resolution may be implemented.

Next, the applied bonding material is patterned to form the plurality of bonding layers BL only on the plurality of second reflection electrodes RE2, respectively. Next, the plurality of light emitting diodes LED may be transferred onto the plurality of formed bonding layers BL, respectively. At this time, the first electrode E1 of each of the plurality of light emitting diodes LED may be inserted into a top surface of the corresponding bonding layer BL to be bonded. Further, each of the plurality of bonding layers BL may be formed to be wider than each of the plurality of light emitting diodes LED. Therefore, even if an alignment error occurs during the process of transferring the plurality of light emitting diodes LED, the plurality of light emitting diodes LED may be stably transferred onto the plurality of bonding layers BL, respectively.

Next, as shown in FIG. 7C, a material for forming the second planarization layer 115 may be applied. At this time, a height of a top surface of the second planarization layer 115 may be formed to be higher than top surfaces of the plurality of bonding layers BL. Further, the height of the top surface of the second planarization layer 115 may be formed to be lower than a height of the top surfaces of the plurality of light emitting diodes LED. Next, the conductive layer CL may be disposed on the second planarization layer 115 and the plurality of light emitting diodes LED exposed by the second planarization layer 115. Further, a photo resist PR for patterning a conductive layer CL may be disposed. At this time, the photo resist PR may be patterned so as to cover each of the plurality of light emitting diodes LED. The plurality of patterned photo resists PR may be disposed on the conductive layer CL so as to cover a top surface and a side surface of each of the plurality of light emitting diodes LED.

Next, as shown in FIG. 7D, a process of etching a plurality of photo resists PR may be performed. As described above, the plurality of photo resists PR may be etched so that a height of top surfaces of the plurality of photo resists PR is lower than a height of top surfaces of the plurality of light emitting diodes LED. Therefore, a part of the conductive layer CL which covers the top surfaces and a part of the side surfaces of the plurality of light emitting diodes LED may be exposed by the plurality of etched photo resists PR.

Next, as shown in FIG. 7E, a process of etching a conductive layer CL exposed by the plurality of photo resists PR may be performed. Therefore, the conductive layer CL in an area not covered by the plurality of photo resists PR may be removed. Next, a material for forming the third planarization layer 116 may be applied on the second planarization layer 115, the conductive layer CL, and the light emitting diodes LED. Further, a patterning process for removing portions of the third planarization layer 116 between the plurality of light emitting diodes LED may be performed. Therefore, portions of the third planarization layer 116 between the plurality of light emitting diodes LED may be removed. At this time, ends of the third planarization layer 116 between the plurality of light emitting diodes LED may be located respectively on the plurality of conductive layers CL. Therefore, the top surface of the second planarization layer 115 may be exposed between the plurality of light emitting diodes LED.

Next, as shown in FIG. 7F, an etching process of a third planarization layer 116 may be performed. The height of the top surface of the third planarization layer 116 may be lowered by the etching process so that the top surfaces of the plurality of light emitting diodes LED may be exposed. The second planarization layer 115 exposed between the plurality of light emitting diodes LED may be etched together by means of the etching process of the third planarization layer 116. Therefore, between the plurality of light emitting diodes LED, the first hole PAC1_H may be formed in the second planarization layer 115, and the second hole PAC2_H may be formed in the third planarization layer 116. At this time, the plurality of conductive layers CL is not etched by an etchant used for etching the third planarization layer 116 so that the plurality of conductive layers CL may serve as a pattern mask. Accordingly, portions of the second planarization layer 115 not covered by the plurality of conductive layers CL between the plurality of light emitting diodes LED may be removed. Further, a part of the etchant permeates to lower portions of the plurality of conductive layers CL so that a part of the portions of the second planarization layer 115 covered by the plurality of conductive layers CL may also be removed. Therefore, the second planarization layer 115 may form an undercut structures between the plurality of light emitting diodes LED. Further, any residual of the bonding layer BL which may remain between the plurality of light emitting diodes LED may be removed together by the etching process of the third planarization layer 116.

Specifically, in the case of a n-up structure in which the cathode electrodes of the light emitting diodes are disposed on an upper portion, the anodes electrode disposed in the lower portion of the plurality of light emitting diodes are to be connected respectively to the plurality of transistors. In one pixel, the plurality of light emitting diodes emit different lights so that the plurality of bonding layers electrically connecting the plurality of transistors and the plurality of light emitting diodes, respectively, should not be electrically connected with each other. Therefore, the plurality of bonding layers are patterned to be completely spaced apart from each other between the plurality of light emitting diodes. Here, a bonding layer disposed so as to correspond to the light emitting diode may be patterned to be disposed wider than the light emitting diode in consideration of a potential defect where the light emitting diode may be erroneously aligned. However, to implement a high resolution of the display device, it is difficult to ensure a sufficient space for spacing the bonding layers patterned to be disposed in a wider area than the light emitting diodes in a situation where the light emitting diodes are small-sized and are densely disposed. As described above, if a sufficient space is not ensured between the plurality of bonding layers, a patterning process for spacing the plurality of bonding layers would need to be more precisely performed so that a probability of occurrence of a patterning defect may increase. If the patterning defect occurs during the formation process of the bonding layers, a residual of the bonding layers due to the patterning defect may remain in the area between the plurality of light emitting diodes. Therefore, the plurality of bonding layers to be spaced apart from each other may be electrically connected so that a short-circuit defect may occur.

Accordingly, the display device 200 according to another example embodiment of the present disclosure includes a plurality of conductive layers CL which protrude respectively from the side surfaces of the plurality of light emitting diodes LED to the outside and are spaced apart from each other. Further, during the etching process of the third planarization layer 116, portions of the second planarization layer 115 not blocked by the plurality of conductive layers CL serving as a pattern mask between the plurality of light emitting diodes LED may be removed. As described above, during the process of removing portions of the second planarization layer 115, the residual of the bonding layer BL which has not been removed between the plurality of light emitting diodes LED due to the patterning defect, if any, may be removed together. Therefore, the plurality of bonding layers BL may be completely separated from each other between the plurality of light emitting diodes LED.

Finally, as shown in FIG. 7G, the connection electrode CE may be disposed on the plurality of light emitting diodes LED exposed by the third planarization layer 116. At this time, the connection electrode CE may have gaps formed at the second hole PAC2_H between the plurality of light emitting diodes LED.

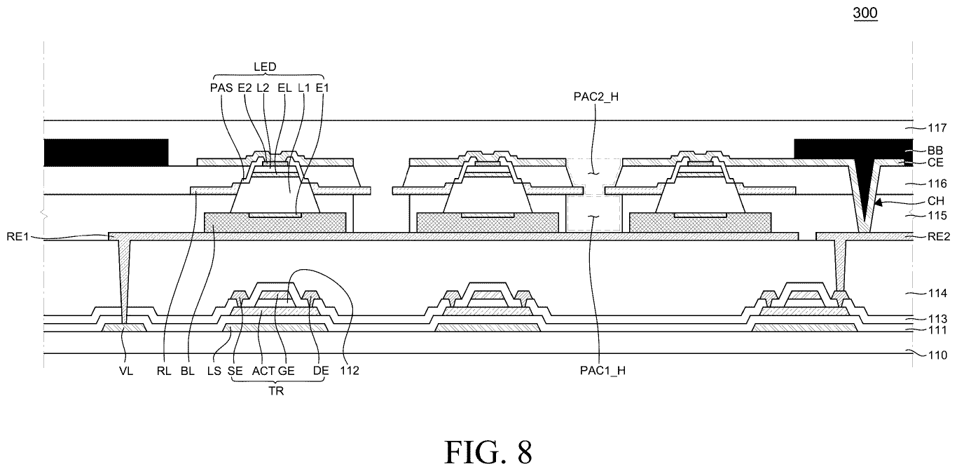

FIG. 8 is a cross-sectional view of a pixel of a display device according to still another example embodiment of the present disclosure. The only difference between the example display device 300 of FIG. 8 and the example display device 100 of FIGS. 1 to 3 is a reflection layer RL, but the other configurations are substantially the same, so that a redundant description may be omitted.

In the display device 300 according to still another example embodiment of the present disclosure, a plurality of conductive layers CL may be reflection layers RL including a reflective material. The reflection layers RL may be disposed at a lower position than the emission layers EL of the plurality of light emitting diodes LED, respectively, in a cross-sectional view. For example, an uppermost edge of a reflection layer RL may be disposed below the bottom surface of the corresponding emission layer EL. Further, the uppermost edge of the reflection layer RL may be disposed to be lower than the uppermost edge of the corresponding first semiconductor layer L1.

In another aspect, the emission layers EL of the light emitting diodes are configured to emit light. Here, light emitted from the emission layers LE is emitted not only toward the upper portion of the substrate. Some of light emitted from the emission layers EL travels toward the side surfaces and the bottom surfaces of the emission layers EL. As described above, the light emitted toward the side surfaces and the bottom surfaces of the emission layers EL is not visible to the user so that there is a problem in that the more the light is emitted toward the side surfaces and the bottom surfaces of the emission layers EL, the worse the luminous efficiency of the light emitting diodes.

Therefore, the display device 300 according to still another example embodiment of the present disclosure may include a plurality of reflection layers RL which protrudes respectively from the side surfaces of the light emitting diodes LED to the outside. Further, the plurality of reflection layers RL may be disposed at a lower position than the emission layers EL of the light emitting diodes LED. At this time, the reflection layers RL may include a material having a high reflectance in consideration of a light reflection efficiency. For example, the reflection layers may use a metal material, such as silver (Ag), aluminum (Al), molybdenum (Mo), titanium (Ti), or an alloy thereof, but is not limited thereto.

As described above, in the display device 300 according to still another example embodiment of the present disclosure, the reflection layers RL may be disposed to be in contact with the side surfaces of the light emitting diodes LED, respectively. Therefore, light emitted from the emission layers EL to the side surfaces and the bottom surfaces may be reflected toward the upper portion of the substrate 110. By doing this, the light extraction efficiency of the light emitting diode LED may be further improved.

In the display device 300 according to still another example embodiment of the present disclosure, the plurality of bonding layers BL may be disposed to be wider than the plurality of light emitting diodes LED. Therefore, even if an alignment error occurs during the process of transferring the plurality of light emitting diodes LED, the plurality of light emitting diodes LED may be more stably transferred onto the plurality of bonding layers BL, respectively.

In the display device 300 according to still another example embodiment of the present disclosure, a plurality of bonding layers BL may include a conductive material. Therefore, in the display device 300 according to still another example embodiment of the present disclosure, the bonding layers BL do not include conductive balls, so that the size of each bonding layer BL may be reduced more. Further, the entire size of the pixel PX including the plurality of bonding layers BL may be reduced. As described above, as the size of the pixel PX is reduced, more pixels PX may be disposed in the same area so that the display device 300 with a higher resolution may be implemented.

In the display device 300 according to still another example embodiment of the present disclosure, the second planarization layer 115 may form an undercut structure between the plurality of light emitting diodes LED by the reflection layer RL. Therefore, the connection electrodes CE may be completely disconnected each other between the plurality of light emitting diodes LED by the undercut structure of the second planarization layer 115.

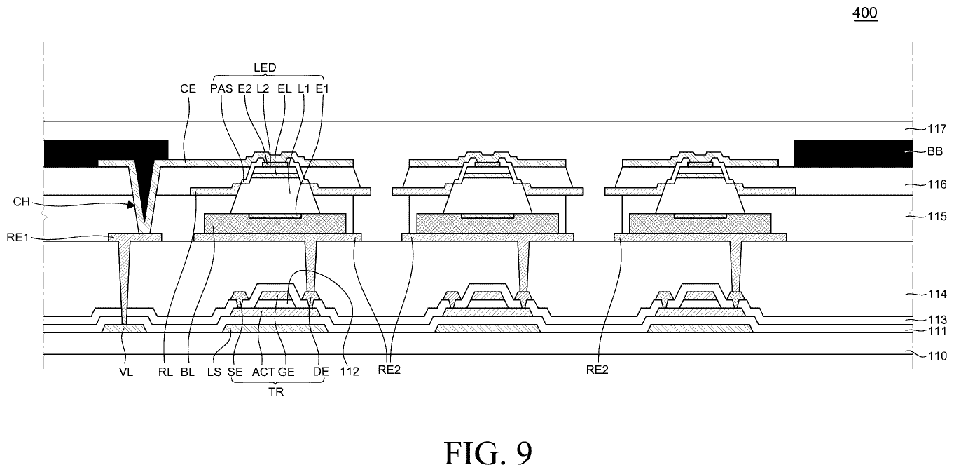

FIG. 9 is a cross-sectional view of a pixel of a display device according to still another example embodiment of the present disclosure. The only difference between an example display device 400 of FIG. 9 and the example display device 200 of FIG. 5 is a reflection layer RL, but the other configurations are substantially the same, so that a redundant description may be omitted. Further, the reflection layer RL of the example display device 400 of FIG. 9 is substantially the same as the reflection layer RL of the example display device 300 of FIG. 8 so that a redundant description may be omitted.

The display device 400 according to still another example embodiment of the present disclosure may include a plurality of reflection layers RL which protrude respectively from the side surfaces of the light emitting diode LEDs to the outside. Further, the plurality of reflection layers RL may be disposed to be at a lower position than the emission layers EL of the plurality of light emitting diodes LED, respectively, in a cross-sectional view. As described above, in the display device 400 according to still another example embodiment of the present disclosure, the reflection layers RL may be disposed to be in contact respectively with the side surfaces of the light emitting diodes LED. Therefore, light emitted from the emission layers EL to the side surfaces and the bottom surfaces may be reflected to the upper portion of the substrate 110. By doing this, the light extraction efficiency of the light emitting diodes LED may be further improved.

In the display device 400 according to still another example embodiment of the present disclosure, the plurality of bonding layers BL may be disposed to be wider than the plurality of light emitting diodes LED, respectively. Therefore, even if an alignment error occurs during the process of transferring the plurality of light emitting diodes LED, the plurality of light emitting diodes LED may be more stably transferred onto the plurality of bonding layers BL, respectively.

In the display device 400 according to still another example embodiment of the present disclosure, a plurality of bonding layers BL may include a conductive material. Therefore, in the display device 400 according to still another example embodiment of the present disclosure, the bonding layers BL do not include conductive balls, so that the size of each bonding layer BL may be reduced more. Further, the entire size of the pixel PX including the plurality of bonding layers BL may be reduced. As described above, as the size of the pixel PX is reduced, more pixels PX may be disposed in the same area so that the display device 400 with a higher resolution may be implemented.

In the display device 400 according to still another example embodiment of the present disclosure, the second planarization layer 115 may form an undercut structure between the plurality of light emitting diodes LED by the plurality of reflection layers RL. Here, during the process of etching the second planarization layer 115, the residual of the bonding layers BL which may remain between the plurality of light emitting diodes LED due to the patterning defect, if any, may be removed together. Therefore, the plurality of bonding layers BL corresponding to the plurality of light emitting diodes LED may be completely disconnected from each other.

The example embodiments of the present disclosure can also be described as follows:

A display device according to an aspect of the present disclosure comprises a substrate, a plurality of reflection electrodes on the substrate, a plurality of boding layers on at least one of the plurality of reflection electrodes, a plurality of light emitting diodes respectively on the plurality of bonding layers, a plurality of conductive layers spaced apart from each other and protruding out respectively from side surfaces of the plurality of light emitting diodes, and at least one connection electrode on the plurality of light emitting diodes.

In one or more embodiments, the display device may further comprise a first planarization layer disposed below the plurality of conductive layers and at least partly covering the side surfaces of the plurality of light emitting diodes and of the plurality of bonding layers; and a second planarization layer disposed above the first planarization layer and partly covering the side surfaces of the plurality of light emitting diodes, wherein each of the first planarization layer and the second planarization layer includes a plurality of holes between the plurality of light emitting diodes

In one or more embodiments, the plurality of conductive layers may be in contact with a top surface of the first planarization layer.

In one or more embodiments, an end portion of one of the plurality of conductive layers may protrude farther out from a side surface of a corresponding one of the plurality of light emitting diodes than an adjacent end portion of the first planarization layer does.

In one or more embodiments, an end portion of one of the plurality of conductive layers protrudes farther out from a side surface of a corresponding one of the plurality of light emitting diodes than an adjacent end portion of the second planarization layer does.

In one or more embodiments, the display device may further comprise a third planarization layer on the plurality of light emitting diodes, wherein the third planarization layer fills the plurality of holes in the first planarization layer and the second planarization layer.

In one or more embodiments, an uppermost end of one of the plurality of conductive layers may be disposed below an active layer of a corresponding one of the plurality of light emitting diodes, and the plurality of conductive layers may include a reflective material.

In one or more embodiments, the plurality of bonding layers may include a conductive black material.

In one or more embodiments, an end of one of the plurality of conductive layers may protrude farther out from a side surface of a corresponding one of the plurality of light emitting diodes than an end of a corresponding one of the plurality of bonding layers does.

In one or more embodiments, the display device may further comprise a power line and a plurality of transistors on the substrate, wherein the plurality of reflection electrodes may include a first reflection electrode electrically connected to the power line and in contact with the plurality of bonding layers, and a plurality of second reflection electrodes spaced apart from the first reflection electrode and electrically connected to the plurality of transistors, respectively.

In one or more embodiments, the at least one connection electrode may include a plurality of connection electrodes electrically connecting the plurality of second reflection electrodes respectively with the plurality of light emitting diodes.

In one or more embodiments, the display device may further comprise a power line and a plurality of transistors on the substrate, wherein the plurality of reflection electrodes may include a first reflection electrode connected to the power line, and a plurality of second reflection electrodes which are spaced apart from the first reflection electrode, are electrically connected respectively to the plurality of transistors, and are respectively in contact with the plurality of bonding layers.

In one or more embodiments, at least one connection electrode may electrically connect the first reflection electrode with the plurality of light emitting diodes.

In one or more embodiments, the at least one connection electrode includes one or more gaps between the plurality of light emitting diodes.

A display device according to another aspect of the present application comprises: a substrate; a power line on the substrate; a plurality of transistors on the substrate; a first reflection electrode connected to the power line; a plurality of second reflection electrodes connected to the plurality of transistors, respectively; a plurality of bonding layers on the first reflection electrode or respectively on the plurality of second reflection electrodes; a plurality of light emitting diodes respectively on the plurality of bonding layers; a plurality of conductive layers respectively covering a part of side surfaces of the plurality of light emitting diodes, an end of one of the plurality of conductive layers protruding farther out from a side surface of a corresponding one of the plurality of light emitting diodes than an end of a corresponding one of the plurality of bonding layers does; and at least one connection electrode connected to the first reflection electrode or respectively to the plurality of second reflection electrodes.

In one or more embodiments, the display device may further comprise a first planarization layer covering side surfaces of the plurality of bonding layers; and a second planarization layer above the first planarization layer and partly covering the side surfaces of the plurality of light emitting diodes, wherein each of the first planarization layer and the second planarization layer includes a hole between adjacent light emitting diodes, among the plurality of light emitting diodes.

In one or more embodiments, the plurality of conductive layers may be disposed between the first planarization layer and the second planarization layer.

In one or more embodiments, the first planarization layer includes an undercut structure between the adjacent light emitting diodes under the one of the plurality of conductive layers.

In one or more embodiments, the first reflection electrode may be spaced apart from the plurality of second reflection electrodes, the plurality of bonding layers may be in contact with the first reflection electrode, and the at least one connection electrode may include the plurality of connection electrodes electrically connecting the plurality of second reflection electrodes with the plurality of light emitting diodes, respectively.

In one or more embodiments, the first reflection electrode may be spaced apart from the plurality of second reflection electrodes, the plurality of bonding layers may be on the plurality of second reflection electrodes, respectively, and the at least one connection electrode may electrically connect the first reflection electrode with the plurality of light emitting diodes.

Although the example embodiments of the present disclosure have been described in detail above with reference to the accompanying drawings, the present disclosure is not limited thereto and may be embodied in many different forms without departing from the technical concept of the present disclosure. Therefore, the example embodiments of the present disclosure are provided for illustrative purposes only and not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate;
a plurality of reflection electrodes on the substrate;
a plurality of boding layers on at least one of the plurality of reflection electrodes;
a plurality of light emitting diodes respectively on the plurality of bonding layers;
a plurality of conductive layers spaced apart from each other and protruding out respectively from side surfaces of the plurality of light emitting diodes; and
at least one connection electrode on the plurality of light emitting diodes.

2. The display device of claim 1, further comprising:
a first planarization layer disposed below the plurality of conductive layers and at least partly covering the side surfaces of the plurality of light emitting diodes and of the plurality of bonding layers; and
a second planarization layer disposed above the first planarization layer and partly covering the side surfaces of the plurality of light emitting diodes,
wherein each of the first planarization layer and the second planarization layer includes a plurality of holes between the plurality of light emitting diodes.

3. The display device of claim 2, wherein the plurality of conductive layers are in contact with a top surface of the first planarization layer.

4. The display device of claim 2, wherein an end portion of one of the plurality of conductive layers protrudes farther out from a side surface of a corresponding one of the plurality of light emitting diodes than an adjacent end portion of the first planarization layer does.

5. The display device of claim 2, wherein an end portion of one of the plurality of conductive layers protrudes farther out from a side surface of a corresponding one of the plurality of light emitting diodes than an adjacent end portion of the second planarization layer does.

6. The display device of claim 2, further comprising:
a third planarization layer on the plurality of light emitting diodes,
wherein the third planarization layer fills the plurality of holes in the first planarization layer and the second planarization layer.

7. The display device of claim 1, wherein:
an uppermost end of one of the plurality of conductive layers is disposed below an emission layer of a corresponding one of the plurality of light emitting diodes; and
the plurality of conductive layers include a reflective material.

8. The display device of claim 1, wherein the plurality of bonding layers include a conductive black material.

9. The display device of claim 1, wherein an end of one of the plurality of conductive layers protrudes farther out from a side surface of a corresponding one of the plurality of light emitting diodes than an end of a corresponding one of the plurality of bonding layers does.

10. The display device of claim 1, further comprising:
a power line and a plurality of transistors on the substrate,
wherein the plurality of reflection electrodes includes:
a first reflection electrode electrically connected to the power line and in contact with the plurality of bonding layers; and
a plurality of second reflection electrodes spaced apart from the first reflection electrode and electrically connected to the plurality of transistors, respectively.

11. The display device of claim 10, wherein the at least one connection electrode includes a plurality of connection electrodes electrically connecting the plurality of second reflection electrodes respectively with the plurality of light emitting diodes.

12. The display device of claim 1, further comprising:
a power line and a plurality of transistors on the substrate,
wherein the plurality of reflection electrodes includes:
a first reflection electrode connected to the power line; and
a plurality of second reflection electrodes which are spaced apart from the first reflection electrode, are electrically connected respectively to the plurality of transistors, and are respectively in contact with the plurality of bonding layers.

13. The display device of claim 12, wherein the at least one connection electrode electrically connects the first reflection electrode with the plurality of light emitting diodes.

14. The display device of claim 13, wherein the at least one connection electrode includes one or more gaps between the plurality of light emitting diodes.

15. A display device, comprising:
a substrate;
a power line on the substrate;
a plurality of transistors on the substrate;
a first reflection electrode connected to the power line;
a plurality of second reflection electrodes connected to the plurality of transistors, respectively;
a plurality of bonding layers on the first reflection electrode or respectively on the plurality of second reflection electrodes;
a plurality of light emitting diodes respectively on the plurality of bonding layers;
a plurality of conductive layers respectively covering a part of side surfaces of the plurality of light emitting diodes, an end of one of the plurality of conductive layers protruding farther out from a side surface of a corresponding one of the plurality of light emitting diodes than an end of a corresponding one of the plurality of bonding layers does; and
at least one connection electrode connected to the first reflection electrode or respectively to the plurality of second reflection electrodes.

16. The display device of claim 15, further comprising:
a first planarization layer covering side surfaces of the plurality of bonding layers; and
a second planarization layer above the first planarization layer and partly covering the side surfaces of the plurality of light emitting diodes,
wherein each of the first planarization layer and the second planarization layer includes a hole between adjacent light emitting diodes, among the plurality of light emitting diodes.

17. The display device of claim 16, wherein the plurality of conductive layers are disposed between the first planarization layer and the second planarization layer.

18. The display device of claim 16, wherein the first planarization layer includes an undercut structure between the adjacent light emitting diodes under the one of the plurality of conductive layers.

19. The display device of claim 15, wherein:
the first reflection electrode is spaced apart from the plurality of second reflection electrodes;
the plurality of bonding layers are in contact with the first reflection electrode; and
the at least one connection electrode includes the plurality of connection electrodes electrically connecting the plurality of second reflection electrodes with the plurality of light emitting diodes, respectively.

20. The display device of claim 15, wherein:
the first reflection electrode is spaced apart from the plurality of second reflection electrodes;
the plurality of bonding layers are on the plurality of second reflection electrodes, respectively; and
the at least one connection electrode electrically connects the first reflection electrode with the plurality of light emitting diodes.
